(19) United States
(12) Patent Application Publication
(10) Pub. No.: US 2026/0354186 A1
(43) Pub. Date: Nov. 5, 2026

(54) COOLING DEVICE FOR A SYSTEM-ON-CHIP

(71) Applicant: Hewlett-Packard Development Company, L.P., Spring, TX (US)

(72) Inventors: Chien-Hua Chen, Corvallis, OR (US); Michael W. Cumbie, Corvallis, OR (US)

(73) Assignee: Hewlett-Packard Development Company, L.P., Spring, TX (US)

(21) Appl. No.: 19/477,938

(22) PCT Filed: May 17, 2023
(86) PCT No.: PCT/US2023/022589

§ 371 Date: Oct. 23, 2025

(51) Int. Cl. H10W 40/47; H10B 80/00; H10D 80/30; H10W 40/20; H10W 40/70; H10W 90/00; H10W 90/10; H10W 90/20

(52) U.S. Cl. CPC H10W 40/47; H10W 40/242; H10W 40/70; H10W 90/736; H10B 80/00; H10D 80/30; H10W 90/10; H10W 90/288

(57) ABSTRACT

A cooling device for a system-on-chip includes a plurality of cooling units to be coupled to a system-on-chip via a first side of the plurality of cooling units and spaced apart from the other cooling units. The cooling device further includes a bridge coupled to a second side of the plurality of cooling units, the bridge and the plurality of cooling units arranged to enable independent movement of individual cooling units of the plurality of cooling units.

### BACKGROUND

Electronic printed circuit boards (PCBs), integrated circuits, and systems-on-chip (SOCs), such as those used in computers or other electronic systems, commonly have a board with electronic components mounted thereon. The electronic components can generate a considerable amount of heat due to electrical power consumption. The heat may be dissipated from the components and the board to ensure proper functioning of the components and to prevent damage to any part of the SOC and the overall electronic system.

### BRIEF DESCRIPTION OF THE DRAWINGS

FIG. 1A is a side view of a system-on-chip assembly;

FIG. 1B is a side view of the system-on-chip assembly FIG. 1A after being heated;

FIG. 2 is a side view of a system-on-chip assembly including a cooling device, according to some examples;

FIG. 3A is a plan view of a system-on-chip assembly including a cooling device, according to some examples;

FIG. 3B is a side view of the system-on-chip assembly of FIG. 3A;

FIG. 3C is a side view of a system-on-chip assembly including a cooling device, according to some examples;

FIG. 4A is a perspective view of a system-on-chip assembly including a cooling device, according to some examples;

FIG. 4B is a perspective view of a system-on-chip assembly including a cooling device, according to some examples;

FIG. 5 is a schematic diagram of a fluid channel path 502 of a cooling unit, according to some examples;

FIG. 6 is a schematic diagram of a liquid cooling system for a system-on-chip, according to some examples.

It will be recognized that the figures are schematic representations for purposes of illustration. The figures are provided for the purpose of illustrating the implementations with the explicit understanding that the figures will not be used to limit the scope of the meaning of the claims.

### DETAILED DESCRIPTION

Heat can be removed from a system-on-chip (SOC) using a variety of techniques. For example, the heat can simply be transferred by convection to ambient air. However, the amount of heat transferred using this method may be relatively low. To enhance the effectiveness of dissipation by convection, a fan can be added to force the air to flow over the component. A heat sink or heat spreader may be attached to the component to further enhance heat dissipation by conducting the heat away from the heat source to a large surface area from which the heat may be dissipated to the air. A heat sink may be a solid piece of material with high thermal conductivity, such as metal, with multiple fins extending from a base coupled to the SOC. The fins increase the surface area of the heat sink, increasing the amount of heat that can be carried away by convection as air or another fluid flows over the heat sink through the fins. For even greater heat dissipation, liquid-cooled heat dissipation systems can be used.

Liquid-cooled systems may include a pump or compressor, a cooling manifold including fluid channels, and a heat sink. The cooling manifold can be coupled to the SOC to allow the heat to transfer from the cooling plate to the cooling fluid. The compressor pumps the cooling fluid through the manifold channels and through pipes or conduits that carry the fluid to the heat sink at a location remote from the SOC. In some cases, the heat sink may include a compressor for active refrigeration of the cooling fluid.

A thermal interface material (TIM) may be positioned between the SOC and the heat sink or cooling manifold to improve the thermal conductivity and heat transfer therebetween. Numerous materials can be used as the TIM, including thermal grease, polymer-based TIMs, carbon-based TIMs, and metal-based TIMs. Metal-based TIMs may have the highest thermal conductivity, as well as low thermal contact resistance, and may thus provide the best heat transfer from the SOC to the heat sink or cooling manifold. These metal-based TIMs may include silver sintering paste, gallium-based liquid metal, solder material, or TIMS including gold or copper bond interfaces.

Some TIMs, including metal-based TIMs such as silver sintering paste, may rigidly bond the heat sink or cooling manifold directly to the SOC. As the SOC heats up during use, differences in temperature as well as differences in thermal expansion coefficients between the SOC, the TIM, and the heat sink or cooling manifold may cause stress on the TIM and the SOC. In larger SOCs, this stress can result in cracking of the, SOC or the TIM and/or delamination of the TIM from the SOC or the heat sink or cooling manifold. Thus, less rigid TIMs, such as thermal grease, two-phase material, or polymer-based TIMs, have typically been used when the SOC size exceeds about 20 mm×20 mm. However, as discussed above, these TIMs may have lower thermal conductivity than metal-based TIMs like silver sintering paste. Accordingly, a solution that allows rigid TIMs to be used on larger SOCs is desirable.

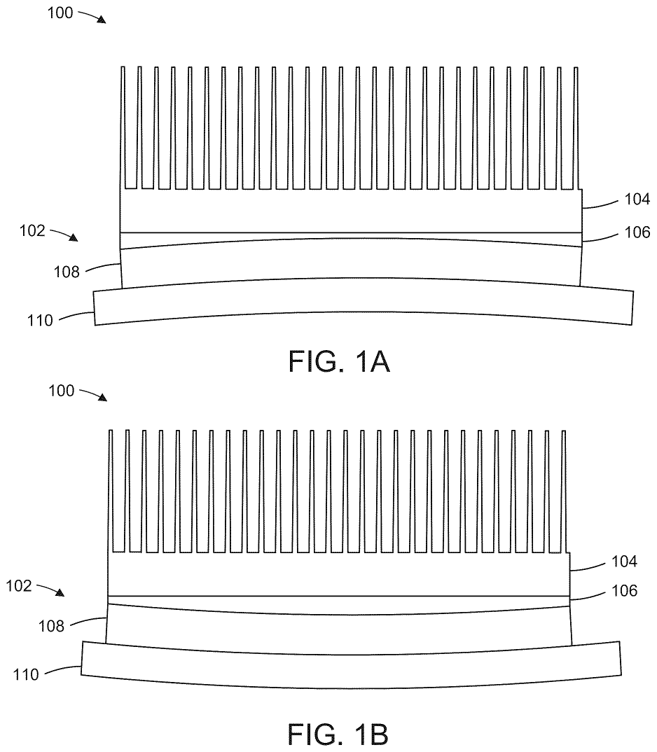

Referring now to FIGS. 1A and 1B, an SOC assembly 100 including a SOC 102 bonded to a heat sink 104 by a TIM 106 is shown in a typical arrangement. The SOC 102 may include processing components 108 mounted to a substrate 110 (e.g., an organic or inorganic substrate). As shown in FIG. 1A, due to manufacturing imperfections, the substrate 110 and the SOC 102 as a whole may be slightly convex, while the lower surface of the heat sink 104 may be substantially flat. It should be understood that the figures are not to scale, and the bends shown in the SOC are exaggerated for clarity. The TIM 106 may be applied when the SOC 102 and heat sink 104 are “cold” (e.g., at room temperature). As the SOC 102 heats up during use and heat is transferred through the TIM 106 to the heat sink 104 and the SOC 102, the TIM 106, and the heat sink 104 undergo thermal expansion. Temperature rise in the SOC during operation may cause a change in SOC shape, increasing the thickness of the TIM 106 more at the center than at the edges when thermal grease or two phase TIM materials are used. This may cause the SOC 102 to straighten or become concave, as shown in FIG. 1B. This may impart significant stresses into the SOC 102 with a rigid TIM, such as a metal TIM, which can result in cracks in the substrate 110 and/or cracks in or delamination of the TIM 106. Differences in thermal expansion coefficients between the heat sink 104, the SOC 102, and the TIM 106 may further contribute to these stresses.

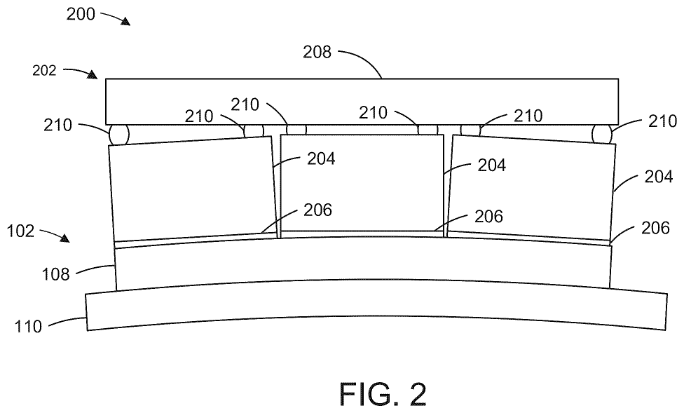

Referring now to FIG. 2, a SOC assembly 200 (e.g., a SOC module) is shown, according to some examples. Instead of a single, unitary heat sink (e.g., heat sink 104), the SOC assembly 200 includes a cooling device 202 that includes multiple cooling units 204 (e.g., heat dissipation modules), each bonded to the SOC 102 by separate TIMs 206 on a first side of each cooling unit 204. The cooling units 204 may be physical heat sinks, each with a plurality of fins to increase the surface area of the heat sink to improve convection, or liquid cooling manifolds (e.g., microchannel manifolds, silicon microchannel manifolds, etc.). Each cooling unit 204 may be spaced apart from the other cooling units 204, allowing each cooling unit 204 to move relative to the other cooling units 204. Because the cooling units 204 are separated from each other, as the SOC 102, cooling units 204, and TIMs 206 heat up, the cooling units 204 can expand toward each other and/or move vertically (as shown) relative to each other without imparting excess stress into the SOC 102 or the TIMs 206. Because the space between the cooling units relieves stress caused by thermal expansion, rigid material, including metal-based TIMs such as silver sintering paste, can be used for the TIMs 206. In some examples, rigid thermal interface materials may refer to thermal interface materials with a modulus of elasticity higher than 15 GPa at room temperature. The SOC assembly 200 thus allows for TIMs with very high thermal conductivity and very low contact resistance to be used despite their rigidity. In some examples, the TIM 206 may be continuous while the cooling units 204 are separated from each other. For example, the SOC assembly 200 may include a single section of TIM 206 bonded to two or more cooling units 204, rather than including a separate section of TIM 206 for each cooling unit 204. The separation of the cooling units 204 may be sufficient to reduce stress without also separating the TIM 206 as shown in FIG. 2.

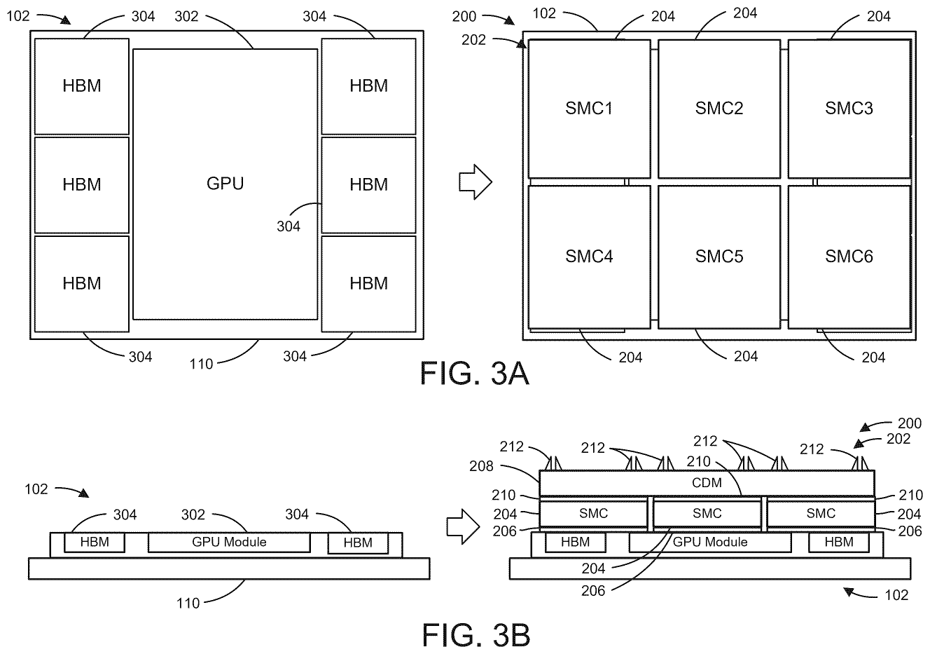

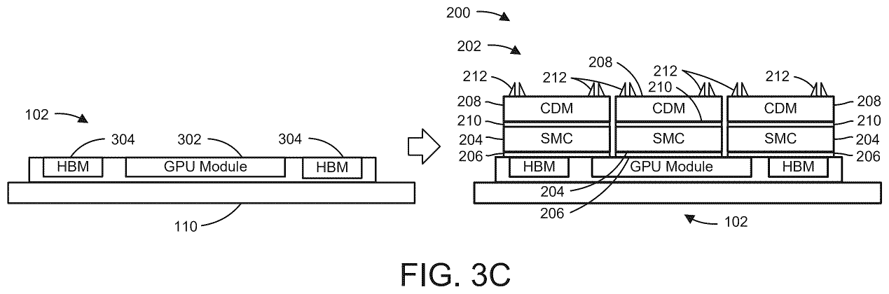

In some examples, the SOC assembly 200 may include a bridge 208 (e.g., a connector, a distributor, a common member, etc.) that connects two or more of the cooling units. In some examples, neither the bridge 208 nor any other incompressible, non-viscous materials may extend into the gaps between the cooling units 204. The bridge 208 and the cooling units 204 may thus enable independent movement of individual cooling units 204 relative to the other cooling units 204, for example, in response to thermal expansion. In some examples, thermal grease or other viscous or compressible materials may be applied to fill the gaps between the cooling units 204, for example, to increase heat conduction between the cooling units 204. In some examples, no material may be positioned between the cooling units 204. For example, in a SOC assembly 200 in which the cooling units 204 are liquid cooling manifolds, the bridge 208 may be a coolant distribution manifold (e.g., a coolant delivery manifold, a fluid distribution manifold, a liquid distribution manifold, etc.) that supplies liquid to the fluid channels of each liquid cooling manifold to which it is connected. In a SOC assembly 200 in which the cooling units 204 are solid, air-cooled heat sinks, the bridge 208 may be a heat conducting structure that further conducts heat away from the cooling units 204 and the SOC 102. For example, the bridge 208 may itself be a heat sink with a plurality of fins to increase the surface area of the bridge 208 to improve convection. Heat may conduct from the SOC 102 into the cooling units 204, and from the cooling units 204 into the bridge 208. Heat may be removed from both the cooling units 204 and the bridge 208 either by natural convection or by forced convection using a fan. The bridge 208 may be coupled to the cooling units 204 by flexible seals 210 on a second side of each cooling unit 204, opposite the first side of each cooling unit 204, which may be bonded to the SOC 102 by a rigid TIM 206, such as a metal-based TIM, but not directly coupled together. The flexible seals 210 may be made of elastomer or other flexible materials. The flexible seals 210 may allow the cooling units 204 to move relative to the bridge 208 without imparting significant stresses into the cooling units 204. The flexible seals 210, in combination with the gaps between the cooling units, may enable independent movement of individual cooling units 204 relative to the other cooling units 204. In some examples, a single flexible seal 210 (e.g., a gasket) may be positioned between the bridge 208 and all of the cooling units 204 or a subset of the cooling units 204. Because the interfaces between the cooling units 204 are farther from the SOC 102 than the TIM 206 is, a flexible material with less thermal conductivity than the TIM 206, such as the flexible seal 210, is acceptable. A bridge 208 coupled to two or more of the cooling units 204 may improve the thermal integration of the system, allowing heat to transfer between cooling units 204, and may also improve the efficiency of coolant distribution when the bridge 208 is a coolant distribution manifold. Liquid-cooled cooling devices 202 are discussed in further detail below with regard to FIGS. 3A-3C. In some examples, a bridge 208 may be coupled to one cooling unit 204. Thus, each cooling unit may include a separate bridge 208. For example, each cooling unit 204 may be a microchannel manifold with its own bridge 208 in the form of a coolant distribution manifold.

The bridge 208 may also allow the cooling device 202 to be fully assembled before being installed on the SOC 102. It may be helpful to have the cooling units 204 very close together such that substantially an entire surface of the SOC 102 (e.g., the upper surface of the SOC 102 as shown in FIG. 2) is covered by the cooling units, with the gaps positioned over an insubstantial portion of the surface. For example, the gap between each cooling unit 204 may be about 200 microns wide or less. Such a small gap may be difficult to maintain if each cooling unit 204 is individually bonded to the SOC 102. Accordingly, each cooling unit 204 may first be coupled to the bridge 208, maintaining a very small gap between the cooling units 204, and the combined cooling units 204 and bridge 208 may be coupled to the SOC 102. This may also allow the cooling devices 202 to be pre-assembled for installation on existing SOCs 102, for example, to replace an existing heat sink. The cooling devices 202 may be manufactured and/or assembled using precision machinery to maintain the very small gaps between the cooling units 204.

Referring now to FIGS. 3A and 3B, the SOC assembly 200 is shown, according to some examples. FIG. 3A shows a plan view of a SOC 102, including a graphical processing unit (GPU) 302 and several high bandwidth memory modules (HBM) 304, as well as an array of cooling units 204 positioned thereupon. FIG. 3B shows a side view of the SOC 102 and the SOC assembly 200 of FIG. 3A. As shown in FIGS. 3A and 3B, a three by two array of cooling units 204, shown as silicon microchannel manifolds, are positioned on the SOC 102. In the example shown, several of the cooling units 204 are bonded to a portion of the GPU 302 and to a portion of a HBM 304. Other cooling units 204 may be bonded only to a portion of the GPU 302. Thus, the cooling units 204 may be arranged irrespective of the layout of the components of the SOC 102. Any numerical array of cooling units 204 may be used. For example, a two by one array, a four by four array, a ten by three array, a six by five array, etc. of cooling units 204 may be coupled to the SOC 102 irrespective to the layout of components of the SOC 102. In other examples, the layout of the cooling units 204 may correspond to the layout of the SOC 102. For example, cooling units 204 approximately the size and shape of the HBMs 304 may be bonded to each HBM 304, and a cooling unit approximately the size and shape of the GPU 302 may be bonded to the GPU 302. Further, the cooling units 204 may be non-rectangular. For example, the cooling units 204 may be L-shaped, round, or any other shape. The cooling units 204 may thus be shaped and arranged according to the cooling needs of the SOC 102.

As shown in FIG. 3B, each cooling unit 204, shown as silicon microchannel manifolds, may be bonded to the SOC 102 by a separate TIM 206. In other examples, a single portion of TIM 206 may couple multiple cooling units 204 (e.g., all of the cooling units 204) to the SOC 102. Because the space between the cooling units 204 allows the cooling units 204 to thermally expand and move relative to each other due to bending and flexing of the SOC 102, a rigid thermal interface material, including metal-based thermal interface materials such as silver sintering paste, may be used as the TIM 206 to bond the cooling units 204 to the SOC 102. Each cooling unit 204 may be coupled to a bridge 208, shown as a coolant distribution manifold. As discussed above, a flexible seal 210 may be positioned between and couple the bridge 208 to each cooling unit 204 to allow the cooling units 204 to move relative to the bridge 208 in response to thermal expansion in the SOC assembly 200. In some examples, each cooling unit 204 may be coupled to the bridge 208 by a separate flexible seal 210. In other examples, a single flexible seal 210 may couple multiple cooling units 204 (e.g., all of the cooling units 204) to the bridge 208.

Each cooling unit 204 may include fluid channels (e.g., coolant channels, liquid channels, etc.) through which coolant can flow. In some examples, each cooling unit may include one fluid channel. The bridge 208 may include coolant distribution channels (e.g., coolant delivery channels, fluid distribution channels, liquid distribution channels, etc.) that may be fluidly coupled to the fluid channels of each cooling unit 204 to supply coolant to the fluid channels. The bridge 208 may include fluid ports 212, which can be coupled to fluid inlet or outlet lines. Coolant (e.g., water, glycols, commercially available coolants, etc.) may be pumped by a pump into an inlet port 212 of the bridge 208, and the bridge 208 may distribute the coolant to the fluid channels of the cooling units 204. The coolant may flow through the coolant channels, absorbing heat that has conducted from the SOC 102, through the TIM 206, to the cooling units 204. The heated coolant may the flow back into a coolant distribution channel or coolant outlet channel in the bridge 208 and out of the bridge 208 via an outlet port 212 to discharge the heated coolant to an outlet line. The outlet line may then carry the heated coolant to a remote heat sink or refrigeration unit, which can then absorb heat from the heated coolant. The pump may then recirculate the cooled coolant back to the cooling device 202.

Coolant may flow from the bridge 208 to the cooling units 204 in series or in parallel. For example, in a series configuration, coolant may flow from the bridge 208 into a first cooling unit 204, back into the bridge 208, and then into a second cooling unit 204 before being discharged from the coolant outlet port 212 of the bridge 208. Coolant may thus flow through two or more cooling units (e.g., through all of the cooling units 204) before being discharged from the bridge 208 via an outlet port 212. Alternatively, in a parallel configuration, the bridge 208 may include separate fluid distribution channels for each cooling unit 204. Thus, coolant may flow from the bridge 208 to each cooling unit 204 and then may be discharged as heated coolant from the bridge 208 via an outlet port 212 without first being supplied to another cooling unit 204. The coolant from each cooling unit 204 may be combined in the bridge 208 before being discharged, may be discharged from the bridge 208 through separate outlet ports and combined thereafter (e.g., before being returned to the pump), or may remain separated from the coolant supplied to the other cooling units in parallel fluid lines as the coolant is recirculated.

FIG. 3C shows the SOC 102 and the SOC assembly 200 according to some other examples. As shown in FIG. 3C, each cooling unit 204 may be coupled to a separate bridge 208, shown coolant distribution manifolds. This arrangement may further reduce stress due to thermal expansion in the SOC assembly 200 because stress cannot be transferred between the cooling units 204 through a common bridge 208. In some examples, a more rigid bond between the cooling unit 204 and the respective bridge 208 may be used rather than the flexible seal 210. This may increase heat transfer between the cooling unit 204 and the bridge 208 and improve the heat-removal capacity of the cooling device 202. In some examples, a bridge 208 may be coupled to multiple cooling units 204 but less than all of the cooling units 204. For example, a cooling device 202 that includes six cooling units 204, as shown in FIGS. 3A-3C, may include three bridges, each coupled to two of the cooling units. Accordingly, each bridge 208 may transmit stress between only the two respective cooling units 204. This may also allow selective thermal integration of the cooling units 204. For example, if a cooling device 202 with a two by two array of cooling units 204 is installed on a SOC 102 in which two of the cooling units 204 are coupled to relatively hot portions of the SOC and two of the cooling units 204 are coupled to relatively cold potions of the SOC, two bridges 208 may be arranged such that each bridge 208 is coupled to one cooling unit 204 coupled to a hot portion and one cooling unit 204 coupled to a cold portion. This may help to distribute the cooling load more evenly between the bridges 208 and may allow for heat to transfer from the cooling units 204 coupled to the hot portions to the cooling units 204 coupled to the cold portions.

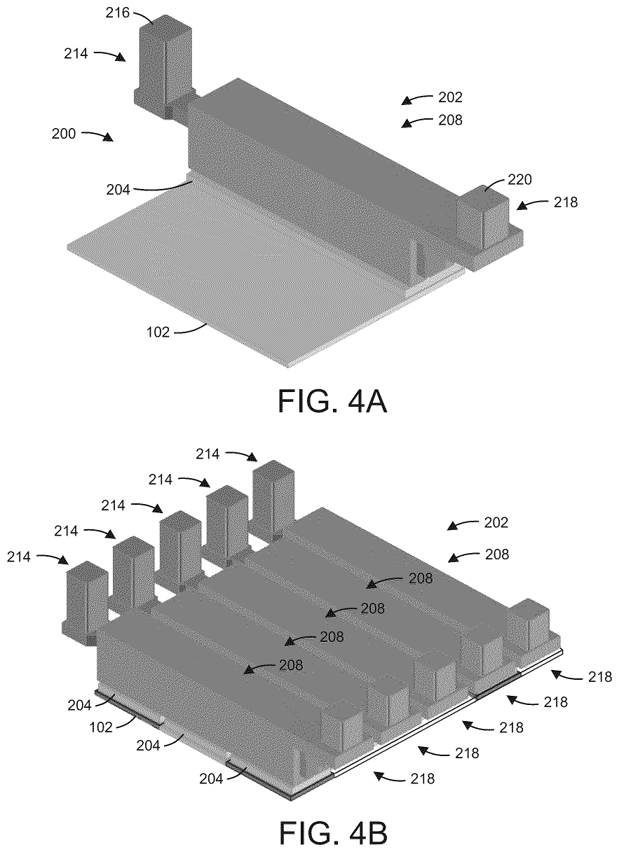

Referring now to FIG. 4A, a perspective view of the SOC assembly 200 is shown, according to some examples. As shown in FIG. 4A, the SOC assembly 200 includes a cooling device 202 that includes a single cooling unit 204 and a single bridge 208, shown as a coolant distribution manifold. The bridge 208 may include an inner manifold 214 (e.g., a lower manifold) including an inlet port 216 and outer manifold 218 (e.g., an upper manifold) including an outlet port 220. The cooling unit 204 may be approximately the length of the SOC 102. In some examples, several cooling units 204 having a length approximately equal to the length of the SOC 102 may be arranged side-by-side such that the SOC is substantially fully covered by the cooling units 204. Each cooling unit 204 may have a corresponding bridge 208 as shown in FIG. 4A. For example, the SOC 102 may be approximately 60 mm×60 mm. The cooling device 202 may include three cooling units 204 approximately 60 mm long and slightly less than 20 mm wide. The three cooling units 204 may be arranged side by side with a small gap between each cooling unit 204, such that the three cooling units 204 cover substantially all of the SOC 102. Each of the cooling units may include an associated bridge.

Referring now to FIG. 4B, a perspective view of the SOC assembly 200 is shown, according to some examples. Each bridge 208 may include an inner manifold 214 and an outer manifold 218, similar to the bridge 208 of FIG. 4A. As shown in FIG. 4B, five bridges 208 are arranged in one by five array. Each bridge 208 is coupled to three cooling units 204. Thus, the cooling units 204 may be arranged in a three by five array covering substantially all of the SOC 102. As discussed above, each bridge 208 may supply coolant to three respective cooling units 204 either in series or in parallel. Each cooling unit 204 may be physically separated and spaced apart from the other two cooling units 204 coupled to the same bridge 208 and the cooling units 204 coupled to the adjacent bridges 208.

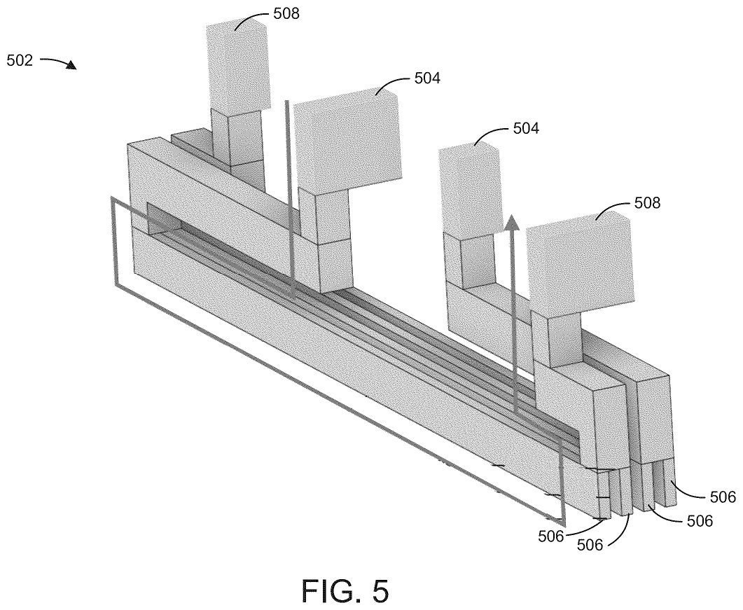

Referring now to FIG. 5, a schematic diagram of a fluid channel path 502 of a cooling unit 204 is shown, according to some examples. The fluid channel path 502 may be machined, 3D printed, or otherwise formed as part of a microchannel manifold (e.g., a silicon microchannel manifold). The fluid channel path 502 may include an inlet 504 arranged to be coupled to an outlet of a bridge 208 (e.g., a coolant distribution manifold). For example, the fluid channel path 502 may be included in the cooling unit 204 shown in FIG. 4A. Coolant may be supplied to the inlet 504 of the fluid channel path and may be separated into two or more lower channels 506. The lower channels 506 may be positioned near the lower end of the cooling units 204. Thus, when the cooling unit 204 is coupled to the SOC 102, the lower channels 506 may be positioned adjacent the SOC 102, maximizing the heat transfer from the SOC 102 to the coolant in the lower channels 506. The heated coolant may then be discharged from the fluid channel path 502 via the outlet 508, back to the bridge 208.

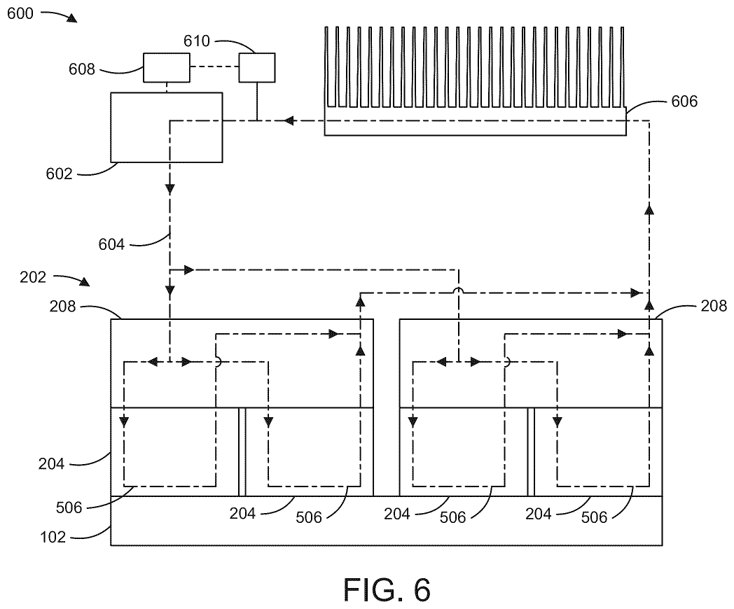

Referring now to FIG. 6, a schematic diagram of a liquid cooling system 600 for a SOC 102 is shown, according to some examples. The system is shown with a cooling device 202 that includes two bridges 208, shown as coolant delivery manifolds, with two cooling units 204, shown as silicon microchannel manifolds, coupled to each bridge 208. It should be understood, as discussed above, that the cooling system may include different number and combinations of cooling units 204 and bridges 208. The system 600 includes a pump 602 configured to pump coolant through the coolant lines 604 (e.g., coolant channels, coolant conduits, etc.). As shown in FIG. 6, the coolant leaving the pump 602 splits between two coolant lines that direct the coolant respectively to the two bridges 208. Each bridge 208 includes coolant channels that further split the coolant into two separate lines 604, each of which may be supplied to one of the cooling units 204. The coolant may be further split into separate parallel channels in the bridge 208 or the cooling unit 204 to disperse the coolant more efficiently over the footprint of the cooling unit 204. As discussed above, in some examples the coolant lines 604 may be arranged in series rather than parallel. For example, coolant may flow from the first bridge 208 to the second bridge 208 and/or may flow from the first cooling unit 204 of each bridge to the second cooling unit 204 of the respective bridge rather than splitting into separate parallel lines 604.

As discussed above with respect to FIG. 5, the cooling units 204 may include lower channels 506 near the lower end of the cooling units 204, so that the coolant can more efficiently draw heat away from the SOC 102. The heated coolant can be discharged from the cooling units 204 and recombined in the bridges 208. The combined heated coolant from each bridge 208 can be discharged from the respective bridge 208 and further combined. The combined heated coolant from both of the bridges 208 can then be directed to a remote heat sink 606, which draws heat away from the coolant, reducing the temperature of the coolant and increasing the temperature of the heat sink 606. The heat sink 606 can then be cooled, for example, via convection. In some examples, the system 600 may include a refrigeration unit instead of or in addition to the heat sink 606 to draw additional heat away from the heated coolant. After the coolant passes by or through the heat sink 606 or refrigeration unit, the coolant may be recycled back to the pump 602 and recirculated through the coolant lines 604.

The system 600 may include a controller 608 configured to control the speed of the pump 602, thereby controlling the circulation rate of the coolant thought the coolant lines 604. The system 600 may include temperature sensors 610 configured to measure the temperature of the coolant in the coolant lines 604. The temperature sensors 610 may be communicatively coupled to the controller 608, and the controller 608 may control the pump 602 based on temperature data received from the temperature sensors 610. For example, if the temperature data indicates an increase in the temperature of the coolant in the coolant line 604 leaving the heat sink 606, the controller 608 may increase the speed of the pump 602 to increase the flow of coolant through the cooling device 202. The controller 608 may also receive temperature data from temperature sensors coupled to the SOC 102. The controller 608 may also be communicatively coupled to other components, including components of the SOC 102 itself, and may receive commands from those components. For example, a processor of the SOC 102 may send a command to the pump controller 608 indicating that components of the SOC (e.g., graphical processing units, central processing units, the processor itself, etc.) is operating or will operate at an elevated utilization. The pump controller 608 may increase the speed of the pump 602 in anticipation of increased temperature of the SOC 102 based on the current or expected elevated utilization.

The controller 608 may include a processing circuit including a processor which can be a single core or multi core processor, or a plurality of processors for parallel processing. The processing circuit may also include memory (e.g., random-access memory, read-only memory, flash memory). The memory may store an application, which may be executed by the processor to control the operation of the pump 602. The controller 608 may include a communication interface (e.g., a network adapter) for communicating with other components of the system 600 (e.g., the temperature sensors 610, the SOC 102, etc.). The controller 608 may communicate with the other components of the system 600, via the communication interface, using a wired or wireless connection (e.g., Bluetooth, Wi-Fi, ZigBee, etc.). The controller 608 can be operatively coupled to a computer network using the communication interface. The network can be, for example, the Internet, an intranet and/or extranet, or an intranet and/or extranet that is in communication with the Internet. In some examples, the network may be a telecommunication and/or data network. The network can include computer servers, which can enable distributed computing, such as cloud computing.

The processing circuit of the controller 608 can execute machine-readable instructions, which can be embodied in a program or software, such as the application. The instructions may be stored in the memory. The instructions can be directed to the processor, which can subsequently program or otherwise configure the processing circuit to implement methods of the present disclosure. The processing circuit can be part of a circuit, such as an integrated circuit. In some cases, the circuit is an application specific integrated circuit (ASIC).

The controller 608 can communicate with remote computer systems through the network. For instance, the controller 608 can communicate with a remote computer system of a user (e.g., e.g., a database, an enterprise or extraprise system, an Internet-of-Things (IoT) device, a sensor, or the like). Examples of remote computer systems include personal computers (e.g., portable PC), slate or tablet PC's (e.g., Apple® iPad, Samsung® Galaxy Tab), telephones, Smart phones (e.g., Apple® iphone, Android-enabled device, Blackberry®), or personal digital assistants.

In an aspect, a cooling device for a system-on-chip is provided. The cooling device includes a plurality of cooling units to be coupled to a system-on-chip via a first side of the plurality of cooling units and spaced apart from the other cooling units. The cooling device further includes a bridge coupled to a second side of the plurality of cooling units. The bridge and the plurality of cooling units are arranged to enable independent movement of individual cooling units of the plurality of cooling units.

In some examples, each cooling unit comprises a heat sink to conduct heat from the system-on-chip, wherein the bridge comprises a heat sink to conduct heat from each cooling unit. In some examples, each cooling unit comprises a plurality of fins and wherein the bridge comprises a plurality of fins.

In some examples, a width of the gap between each cooling unit is about 200 microns or less.

In some examples, each cooling unit comprises a microchannel manifold including a fluid channel, wherein the bridge comprises a coolant distribution manifold to supply fluid to the fluid channel of each cooling unit. In some examples, the bridge comprises a coolant inlet port to receive coolant, a plurality of coolant distribution channels to supply coolant to the fluid channel of each cooling unit, and a coolant outlet port to discharge heated coolant received from the fluid channel of each cooling unit. In some examples, the plurality of coolant distribution channels are arranged in parallel such that heated coolant from the fluid channel of each cooling unit is discharged from the coolant outlet port without first being supplied to the fluid channel of another cooling unit. In some examples, the plurality of coolant distribution channels are arranged in series such that heated coolant from the fluid channel of a first cooling unit is supplied to the fluid channel of a second cooling unit before being discharged from the coolant outlet port.

In some examples, the cooling device includes a flexible seal positioned between the bridge and each cooling unit to allow movement of the plurality of cooling units relative to the bridge.

In some examples, the cooling device includes a metal-based thermal interface material to bond the plurality of cooling units to the system-on-chip.

In some examples, the gap between each cooling unit is filled with thermal grease.

In another aspect a cooling device for a system-on-chip is provided. The cooling device includes a plurality of microchannel manifolds to be coupled to a system-on-chip via a first side of the plurality of microchannel manifolds and spaced apart from the other microchannel manifolds. Each microchannel manifold of the plurality of microchannel manifolds includes a fluid channel. The cooling device further includes a coolant delivery manifold coupled to a second side of the plurality of microchannel manifolds and including a plurality of coolant delivery channels to deliver coolant to the fluid channel of each microchannel manifold. The coolant delivery manifold and the plurality of microchannel manifolds are arranged to enable independent movement of individual microchannel manifolds of the plurality of microchannel manifolds

In some examples, the coolant delivery manifold comprises a coolant inlet port to receive coolant and a coolant outlet port to discharge heated coolant received from the fluid channel of each microchannel manifold. In some examples, the plurality of coolant delivery channels are arranged in parallel such that heated coolant from the fluid channel of each microchannel manifold is discharged from the coolant outlet port without first being supplied to the fluid channel of another cooling unit. In some examples, the plurality of coolant delivery channels are arranged in series such that heated coolant from the fluid channel of a first microchannel manifold is supplied to the fluid channel of a second microchannel manifold before being discharged from the coolant outlet port.

In another aspect, a system-on-chip module is provided. The system-on-chip modules includes a system-on-chip that produces heat upon operation thereof and a plurality of heat dissipation modules to be coupled to the system-on-chip and spaced apart from the other heat dissipation modules. The system-on-chip module further includes a connector coupled to the plurality of heat dissipation modules opposite the system-on-chip. The connector and the plurality of heat dissipation modules are arranged to enable independent movement of individual heat dissipation modules of the plurality of heat dissipation modules.

In some examples, each heat dissipation module of the plurality of heat dissipation modules is bonded to the system-on-chip by a metal-based thermal interface material. In some examples, the thermal interface material is silver sintering paste. In some examples, each heat dissipation module of the plurality of heat dissipation modules is coupled to the connector by an elastomer seal.

In some examples, a width of the gap between each heat dissipation module of the plurality of heat dissipation modules is about 200 microns or less, and the plurality of heat dissipation modules are arranged in an array covering substantially an entire surface of the system-on-chip.

It should be noted that certain passages of this disclosure may reference terms such as “first” and “second” in connection with devices, surfaces or sides of devices, modes of operation, transmit chains, antennas, etc., for purposes of identifying or differentiating one from another or from others. These terms are not intended to merely relate entities (e.g., a first device and a second device) temporally or according to a sequence, although in some cases, these entities may include such a relationship. Nor do these terms limit the number of possible entities (e.g., devices) that may operate within a system or environment.

It should be understood that the systems described above may provide multiple ones of any or each of those components and these components may be provided on either a standalone machine or, in some implementations, on multiple machines in a distributed system. In addition, the systems and methods described above may be provided as computer-readable programs or executable instructions embodied on or in articles of manufacture. The article of manufacture may be a floppy disk, a hard disk, a CD-ROM, a flash memory card, a PROM, a RAM, a ROM, or a magnetic tape. In general, the computer-readable programs may be implemented in any programming language, such as LISP, PERL, C, C++, C#, PROLOG, or in any byte code language such as JAVA. The software programs or executable instructions may be stored on or in articles of manufacture as object code.

While this specification contains specific implementation details, these should not be construed as limitations on the scope of what may be claimed but rather as descriptions of features specific to particular implementations. Certain features described in this specification in the context of separate implementations can also be implemented in combination in a single implementation. Conversely, various features described in the context of a single implementation can also be implemented in multiple implementations separately or in any suitable sub-combination. Moreover, although features may be described as acting in certain combinations and even initially claimed as such, features from a claimed combination can, in some cases, be excised from the combination, and the claimed combination may be directed to a sub-combination or variation of a sub-combination.

As utilized herein with respect to structural features (e.g., to describe shape, size, orientation, direction, relative position, etc.), the terms “approximately,” “about,” “substantially,” and similar terms are meant to cover minor variations in structure that may result from, for example, the manufacturing or assembly process and are intended to have a broad meaning in harmony with the common and accepted usage by those of ordinary skill in the art to which the subject matter of this disclosure pertains. Accordingly, these terms should be interpreted as indicating that insubstantial or inconsequential modifications or alterations of the subject matter described and claimed are considered to be within the scope of the disclosure as recited in the appended claims.

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other examples, and that such variations are intended to be encompassed by the present disclosure.

The herein described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the foregoing description and the following appended claims may contain usage of the introductory phrases “at least one” and “one or more,” such as to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative examples has been presented for purposes of illustration and of description. It is not intended to be exhaustive or limiting with respect to the precise form disclosed, and modifications and variations are possible considering the above teachings or may be acquired from practice of the disclosed examples. It is intended that the scope of the claimed subject matter be defined by the claims appended hereto and their equivalents.

1-15. (Canceled)

16. A cooling device comprising:
a plurality of cooling units to be coupled to an electronic component via a first side of each of the plurality of cooling units and spaced apart from the other cooling units, each cooling unit of the plurality of cooling units comprising at least one fluid channel; and
a coolant delivery manifold, coupled to a second side of each of the plurality of cooling units, and including a plurality of coolant delivery channels to deliver coolant to the at least one fluid channel of each of the plurality of cooling units, the coolant delivery manifold and the plurality of cooling units arranged to enable independent movement of individual cooling units of the plurality of cooling units.

17. The cooling device of claim 16, wherein each of the cooling units are microchannel manifolds.

18. The cooling device of claim 16, wherein the coolant delivery manifold is coupled to each of the plurality of cooling units by one of: a flexible seal; and flexible seals.

19. The cooling device of claim 16, wherein the coolant delivery manifold is coupled to each of the plurality of cooling units by a single gasket.

20. The cooling device of claim 16, wherein the coolant delivery manifold is coupled to a subset of the plurality of cooling units by a single gasket.

21. The cooling device of claim 16, wherein the flexible seal or flexible seals allow the cooling units to move relative to the coolant delivery manifold without imparting significant stresses into the cooling units.

22. The cooling device of claim 16, wherein the electronic component is a system-on-chip (SOC) and further wherein the cooling units are arranged in a numerical array to substantially cover an entire surface of the system-on-chip.

23. The cooling device of claim 16, further comprising a plurality of coolant delivery manifolds, each coupled to at least one cooling unit.

24. The cooling device of claim 16, wherein the gap between each cooling unit is about 200 microns wide or less.

25. The cooling device of claim 16, wherein the coolant delivery manifold comprises a coolant inlet port to receive coolant and a coolant outlet port to discharge heated coolant received from the fluid channel of each microchannel manifold and wherein the plurality of coolant delivery channels are arranged in parallel such that heated coolant from the fluid channel of each cooling unit is discharged from the coolant outlet port without first being supplied to the fluid channel of another cooling unit.

26. The cooling device of claim 16, wherein the at least one fluid channel further comprises two or more lower channels positioned near the lower end of each of the cooling units such that when the cooling device is coupled to an electronic component they are positioned adjacent the electronic component to maximize the heat transfer from the electronic component to the lower channels.

27. The cooling device of claim 22, wherein the cooling units are bonded to a system-on-chip.

28. A system-on-chip module comprising:
a plurality of cooling units bonded to the system-on-chip via a first side of each of the plurality of cooling units and spaced apart from the other cooling units, each cooling unit of the plurality of cooling units comprising at least one fluid channel; and
a coolant delivery manifold, coupled to a second side of each of the plurality of cooling units, and including a plurality of coolant delivery channels to deliver coolant to the at least one fluid channel of each of the plurality of cooling units, the coolant delivery manifold and the plurality of cooling units arranged to enable independent movement of individual cooling units of the plurality of cooling units.

29. The system-on-chip module of claim 28, wherein the coolant delivery manifold is coupled to each of the plurality of cooling units by one of: a flexible seal; and flexible seals.

30. The system-on-chip module of claim 28, wherein each heat dissipation module of the plurality of heat dissipation modules is bonded to the system-on-chip by a thermal interface material with a modulus of elasticity above 15 GPa.
